(19) United States
(12) Patent Application Publication
(10) Pub. No.: US 2018/0105924 A1
(43) Pub. Date: Apr. 19, 2018

(54) Vapor Deposition Crucible

(71) Applicant: Shenzhen China Star Optoelectronics Technology Co., Ltd., Shenzhen City (CN)

(72) Inventors: Yawei Liu, Shenzhen City (CN); Yang Liu, Shenzhen City (CN)

(21) Appl. No.: 15/112,426

(22) PCT Filed: Apr. 25, 2016
(86) PCT No.: PCT/CN2016/080105

§ 371 Date: Jul. 18, 2016

(30) Foreign Application Priority Data
Mar. 21, 2016 (CN) 201610161257.4

(51) Int. Cl. C23C 14/24

(52) U.S. Cl. CPC C23C 14/243

(57) ABSTRACT

The present invention provides a vapor deposition crucible, comprising a metal bar with material cut by mechanical processing, during the mechanical processing of the metal bar, retaining a portion of thermal conduction structure to transfer heat to center of the crucible, like increasing an inner surface area of the sidewall of the crucible, or arrange a thermal conduction structure like a thermal conduction bar or a thermal conduction plate, to increase contact surface area between evaporation material and the vapor deposition crucible, result in evaporation material to be evenly heated, stabilize the evaporation speed, and then improve the effect of the vapor deposition.

### FIELD OF THE INVENTION

The present invention relates to a display technology field, and more particularly to a vapor deposition crucible.

### BACKGROUND OF THE INVENTION

Organic light-emitting diode (OLED) display is a very promising flat panel display technology, that possesses a very excellent display performance, particularly self luminescence, simple structure, ultra thin, fast response, wide viewing angle, low power consumption, flexible display and so on, known as a “dream monitor”, together with its production equipment investment is far less than Thin Film Transistor Liquid Crystal Display (TFT-LCD), obtained the favor of all the major manufacturers of display, has become the main force of third-generation display device in the field of display technology. Currently OLED has been in the eve of mass production, together with the further research and the emergence of new technology, OLED display will have a breakthrough development.

There are two kinds of preparation process methods for the thin film of organic material for OLED. The polymer material for OLED comprises solution film-forming and this kind of process is still in the pilot study stage. Currently the small molecule material for OLED commonly comprises vacuum thermal evaporation film-forming, this process method is employed by most of the factories of the flat panel display manufacturers, like Samsung and LG and so on. The vacuum thermal evaporation technology comprises heating the material form solid to vapor state in a vacuum environment with pressure under 5×10⁻⁵ Pa, the high-speed moving gaseous molecules reach the glass substrate and deposited and cured on the substrate, then become a solid film of OLED material. The melting type material changes from solid state to liquid state and then to gaseous molecules by heating; this type of material is not highly demanding the interior shape of the crucible, because the liquid material fluids everywhere and will keep fully contact with inner wall of the crucible. The sublimation type material changes directly from solid state to gaseous molecule by heating. Because the solid material is lacking of liquidity, the case shown in FIG. 1 is most likely to occur during the process of sublimating of the material. We can see in FIG. 1, by heating the material 100, the material 100 that contacting the crucible inner wall 200 sublimates and turns into a gaseous molecule and runs away, the remaining solid material cannot flow, and then remaining material 100 cannot fully contact with crucible inner wall 200, result in unstable sublimation speed. If the tool operates at fixed speed mode, the equipment continuously heat up to raise the temperature to keep sublimation speed, it is most likely exceeding the decomposition temperature of material 100 then leads to material deterioration.

### SUMMARY OF THE INVENTION

An object of the invention is to provide a vapor deposition crucible, increasing contacting area between an evaporation material and a crucible body, the evaporation material is uniformly heated, stabilize the evaporation speed, and then improve the effect of evaporation.

For realizing the aforesaid objective, the present invention provides a vapor deposition crucible, comprising a crucible end and a sidewall connected to the crucible end, the sidewall and the crucible end enclosing a hollow chamber, the hollow chamber comprises several inter-connected blind holes and the extending directions consist with the extending direction of the sidewall, an inner surface of the sidewall comprises several first arc shape surfaces curved inward the inner surface of the sidewall, the several first arc shape surfaces are respectively part of the several blind holes.

Wherein the hollow chamber consists of three blind holes at least, that means when the inner surface of the sidewall is comprising at least three first arc shape surfaces, the vapor deposition crucible also comprises a thermal conduction bar located inside the hollow chamber in a case of its bottom is connected with the crucible end; wherein a side surface of the thermal conduction bar is enclosed by several second arc shape surfaces curved inward the surface of thermal conduction bar, the several second arc shape surfaces are respectively part of the several blind holes, that means are respectively located at the same blind holes where the first arc shape surfaces are located; a height of the thermal conduction bar do not exceed two-thirds of a height of the sidewall.

The vapor deposition crucible is made by a metal rod with material removed by mechanical processing.

The present invention also provides another vapor deposition crucible, comprising a crucible end, a sidewall connected to the crucible end, a thermal conduction bar located in a hollow chamber enclosed by the sidewall and the crucible end, and its bottom is connected to the crucible end.

A height of the thermal conduction bar does not exceed two-thirds of a height of the sidewall; the sidewall is barrel shape, the thermal conduction bar is column shape and located at an axis position of the sidewall.

The vapor deposition crucible is made by a metal rod with material removed by mechanical processing.

The present invention also provides a vapor deposition crucible, comprising a crucible end, a sidewall connected to the crucible end, several discontinuous thermal conduction plates located in a shallow chamber enclosed by the sidewall and the crucible end, and its bottom is connected to the crucible end.

The side wall is barrel shape, the several thermal conduction plates are several arc shape thermal conduction plates located at a barrel that is on the same axis with the sidewall; a height of the thermal conduction plate do not exceed two-thirds of a height of the sidewall.

The side wall is barrel shape, the several thermal conduction plates are straight shape, one side of the thermal conduction plate connected inner surface of the sidewall, the other side extends to the axis of the sidewall; a height of the thermal conduction plate do not exceed two-thirds of a height of the sidewall.

The vapor deposition crucible is made by a metal rod with material removed by mechanical processing.

The benefits of the present invention are: the present invention provides a vapor deposition crucible, comprising a metal bar with material cut by mechanical processing, during the mechanical processing of the metal bar, retaining a portion of thermal conduction structure to transfer heat to center of the crucible, like increasing an inner surface area of the sidewall of the crucible, or arrange a thermal conduction structure like a thermal conduction bar or a thermal conduction plate, to increase contact surface area between evaporation material and the vapor deposition crucible, result in evaporation material to be evenly heated, stabilize the evaporation speed, and then improve the effect of the vapor deposition.

In order to further understand the features and technical contents of the present invention, please reference below for a detailed description of the invention and drawings, drawings provide for reference and explanation only, however are not used to limit the invention.

### BRIEF DESCRIPTION OF THE DRAWINGS

Combining with drawings below and detailed descriptions for specific embodiments of the present invention, then the technical solutions and other benefits of the present invention is obviously.

In drawings:

FIG. 1 is a diagram of sublimation type material that is non-uniformly heated during evaporation process in a current vapor deposition crucible;

FIGS. 2 to 3 is sectional diagrams of a first embodiment of the vapor deposition crucible of the present invention;

FIGS. 4 to 7 is top view diagrams of the first embodiment of the vapor deposition crucible of the present invention;

FIG. 8 is a sectional diagram of a second embodiment of the vapor deposition crucible of the present invention;

FIG. 9 is a top view diagram of the second embodiment of the vapor deposition crucible of the present invention;

FIG. 10 is a sectional diagram of a third embodiment of the vapor deposition crucible of the present invention;

FIG. 11 is a top view diagram of the third embodiment of the vapor deposition crucible of the present invention;

FIG. 12 is a sectional diagram of a fourth embodiment of the vapor deposition crucible of the present invention; and

FIG. 13 is a top view diagram of the fourth embodiment of the vapor deposition crucible of the present invention.

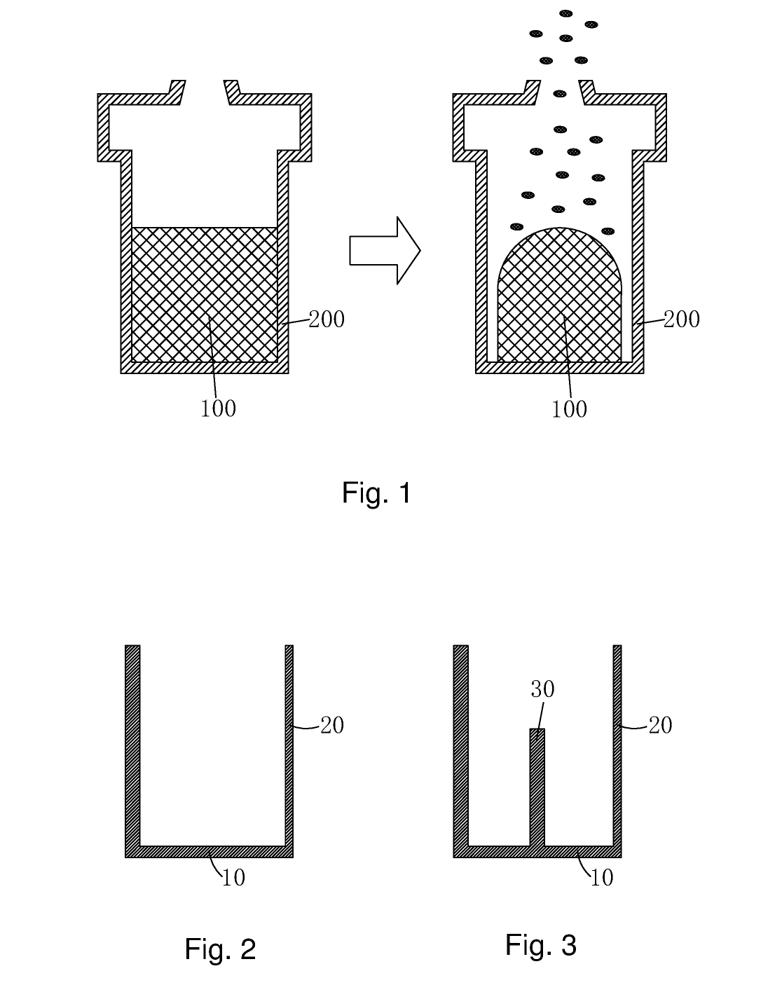

### DETAILED DESCRIPTION OF PREFERRED EMBODIMENTS

For further elaborating the technical solution in present invention and the effect, the present invention will be further described in detail with specific embodiment and attached drawings.

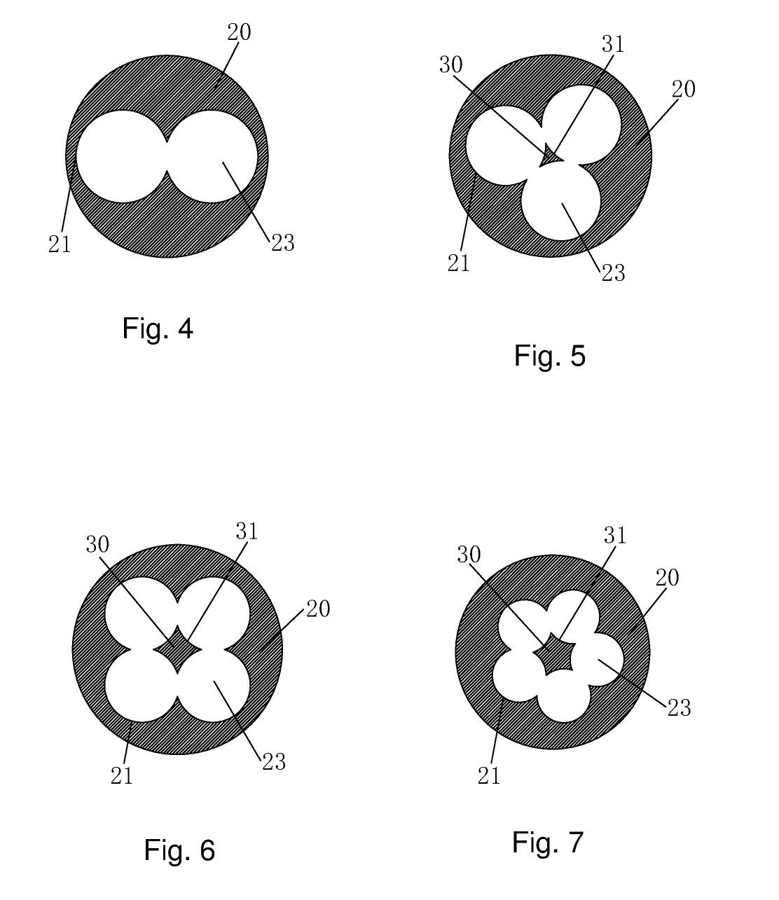

Please refer to FIGS. 2 to 7, the first embodiment of the vapor deposition crucible of the present invention provides, the vapor deposition crucible comprises a crucible end 10 and a sidewall 10 attached to the crucible end 10, a shallow chamber enclosed by the sidewall 20 and the crucible end 10, the shallow chamber comprises several blind holes 23 that is inter-connected, and its extending direction and the extending direction of the sidewall 20 are the same, an inner surface of the sidewall 20 comprises several first arc surfaces 21 curved inward the sidewall 20, the several first arc surfaces are respectively a part of the wall of the several blind holes 23.

Specifically, a material of the crucible end 10 and the sidewall 20 is metal, for example titanium or aluminum and so on.

Please refer to FIG. 3. and FIGS. 5 to 7, wherein a shallow chamber comprises three or more blind holes 23, that means an inner surface of the sidewall 20 comprises three or more first arc surfaces 21, the vapor deposition crucible also comprises a thermal conduction bar 30 located inside the shallow chamber with its bottom connected to the crucible end 10, a side surface of the thermal conduction bar 30 is enclosed by several second arc surfaces 31 that curved inward the thermal conduction bar 30, the several second arc surfaces 31 are respectively part of walls of the several blind holes 23, that means are respectively located at the same blind hole 23 where the first arc surface 21 is located.

Specifically, a height of the thermal conduction bar 30 do not exceed two-thirds of a height of the sidewall 20.

Specifically, a material of the thermal conduction bar 30 is a metal like titanium or aluminum and so on.

Specifically, the vapor deposition crucible of the first embodiment of the present invention is made by a metal rod with material cut by mechanical processing.

The vapor deposition crucible of the first embodiment of the present invention is made from a metal bar that is machined with several inter connected blind holes 23, and the inner surface of the sidewall 20 of the vapor deposition crucible is enclosed by the several first arc surfaces that curved inward the sidewall 20, increase a surface area of a crucible inner wall and then increase a contact area between a crucible body and an evaporation material, thus the evaporation material is uniformly heated, and the evaporation speed is stabilized. Furthermore, the rod is machined with three or more inter connected blind holes 23, and the position of the several blind holes 23 are adjusted, then a thermal conduction bar 30 located inside a sidewall 20 is obtained; a side surface of the thermal conduction bar 30 is enclosed by the several second arc surfaces 31 that curved inward the thermal conduction bar 30, and then increase a contact area between an evaporation material and a crucible body, thus then the evaporation material is uniformly heated, and the evaporation speed is stabilized.

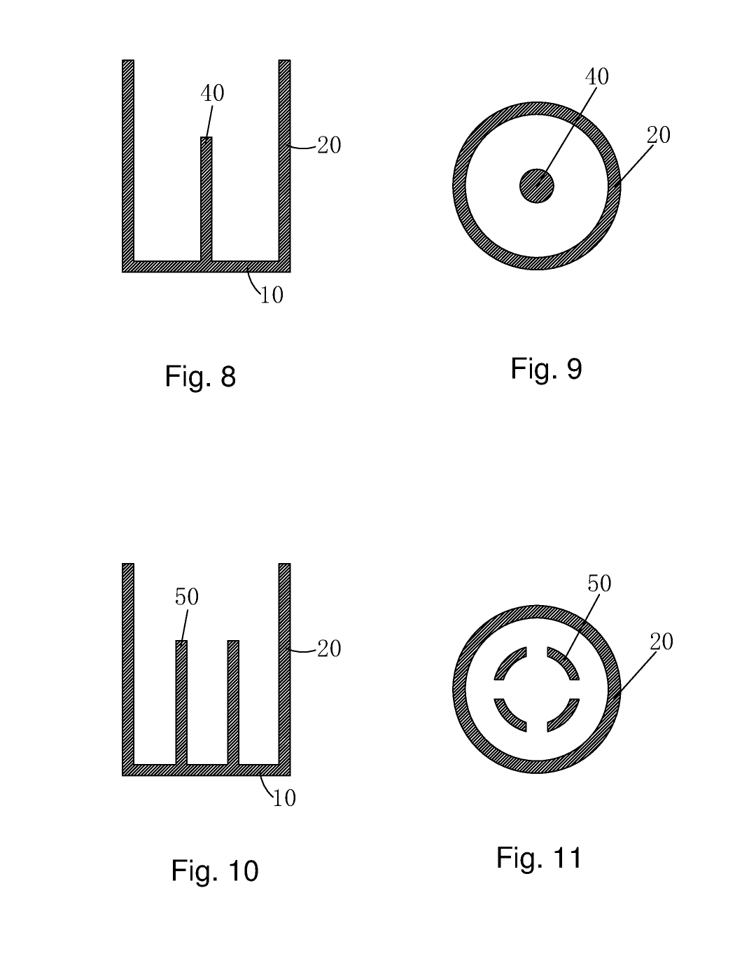

Please refer to FIG. 8 and FIG. 9, a second embodiment of a vapor deposition crucible of the present invention, the vapor deposition crucible comprises a crucible end 10, a sidewall 20 connected to the crucible end 10, and a thermal conduction bar 40 located inside a shallow chamber, that is enclosed by the sidewall 20 and the crucible end 10, and its bottom is connected to the crucible end 10.

Specifically, a height of the thermal conduction bar 40 is less than two-thirds of a height of the sidewall 20.

Specifically, the sidewall 20 is barrel shape, and the thermal conduction bar is column shape and is located at an axis position of the sidewall 20.

Specifically, a material of the crucible end 10, the sidewall 20, and the thermal conduction bar 40 is a metal like titanium or aluminum and so on.

Specifically, the vapor deposition crucible of the second embodiment of the present invention is made by a metal rod with material cut by mechanical processing.

The vapor deposition crucible of the second embodiment of the present invention is made by a metal bar, cutting with a cylinder rod inside, comprising a thermal conduction rod 40 located inside the vapor deposition crucible, increasing a contact area between a crucible body and a evaporation material and the material is uniformly heated, then a center of the evaporation material is heated because the thermal conduction rod is located at the center inside the crucible, then increasing the heated uniformity of all portion of the evaporation material, thus the evaporation speed is stabilized and enhancing the effect of the evaporation.

Please refer to FIG. 10 and FIG. 11, a third embodiment of a vapor deposition crucible of the present invention, the vapor deposition crucible comprises a crucible end 10, a sidewall 20 connected to the crucible end 10, and several discontinuous thermal conduction plates 50 located inside a shallow chamber, that is enclosed by the sidewall 20 and the crucible end 10, and its bottom is connected to the crucible end 10.

Wherein the third embodiment shown in FIGS. 10 and 11, the sidewall 20 is barrel shape, the several thermal conduction plates 50 are several arc shape plates located at a cylinder that is concentric with the sidewall 20.

Specifically, a height of the thermal conduction plates 50 is no more than two-thirds of a height of the sidewall 20

Specifically, a material of the crucible end 10, the sidewall 20, and the thermal conduction plate 50 is a metal like titanium or aluminum and so on.

Specifically, the vapor deposition crucible of the third embodiment is made by a metal rod with material cut by mechanical processing.

A production method of the vapor deposition crucible in the third embodiment of the present invention is: first, an annular cylinder and a cylinder located at the center rod are dug off from a metal bar, then formed a barrel shape sidewall 20 and a barrel inside the sidewall 20, and then processed on a number of vertical slits in the barrel, resulting in a number of discontinuous arc thermally conductive plates 50, the present invention comprises several thermal conduction plates 50 to increase contact area between the crucible body and the evaporation material, and then the evaporation material is uniformly heated, and stabilize the evaporation speed, and improve the effect of evaporation, wherein gaps are located between these thermal conduction plates 50, then the evaporation material inside the crucible is connected, further the thermal transmission effect is enhanced and heated uniformity of the material is improved.

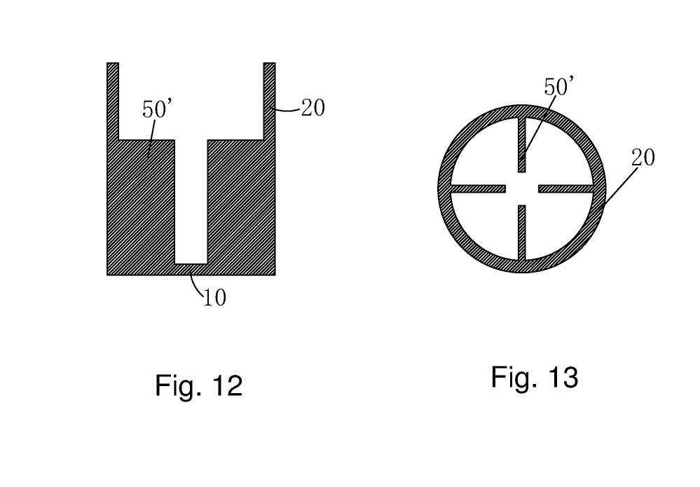

Please refer to FIG. 12 and FIG. 13, a fourth embodiment of a vapor deposition crucible of the present invention, wherein a vapor deposition crucible comprising a crucible end 10, a sidewall 20 connected with the crucible end 10, and several discontinuous thermally conductive plates 50 located in a hollow chamber enclosed by the sidewall 20 and the crucible end 10, and the bottom connected to the crucible end 10;

Wherein the fourth embodiment shown in FIGS. 12 and 13, the sidewall 20 is barrel shape, the several thermal conduction plates 50 present flat, one side of the several thermal conduction plates is connected to a inner surface of the sidewall 20, the other side extends to an axis of the sidewall 20.

Specifically, a height of the thermal conduction plate 50 does not exceed two-thirds of a height of the sidewall 20.

Specifically, a material of the crucible end 10, the sidewall 20, and the thermal conduction plate 50 is metal, for example titanium or aluminum and so on.

Specifically, the vapor deposition crucible of the fourth embodiment is made by a metal rod with material cut by mechanical processing.

A vapor deposition crucible of the fourth embodiments of the present invention is made by digging out several irregular pillars in a metal bar, the present invention comprises several thermal conduction plates 50 extending into the crucible, that located at the sidewall 20 of the vapor deposition crucible, increasing contact area between the crucible body and the evaporation material, and then the evaporation material is uniformly heated, and stabilize the evaporation speed, and improve the effect of evaporation; wherein gaps are between the thermal conduction plates 50, then the evaporation material inside the crucible is connected, further the thermal transmission effect inside material is enhanced and heated uniformity of the material is improved.

In conclusion, the present invention provides a vapor deposition crucible, comprising a metal bar with material cut by mechanical processing, during the mechanical processing of the metal bar, retaining a portion of thermal conduction structure to transfer heat to center of the crucible, like increasing an inner surface area of the sidewall of the crucible, or arrange a thermal conduction structure like a thermal conduction bar or a thermal conduction plate, to increase contact surface area between evaporation material and the vapor deposition crucible, result in evaporation material to be evenly heated, stabilize the evaporation speed, and then improve the effect of the vapor deposition.

The above provides only specific embodiments of present invention, the scope of the present invention is not limited to this, and to any persons who are skilled in the art, change or replacement which is easily derived should be covered by the protected scope of the invention. Thus, the protected scope of invention should go by the subject claims.

What is claimed is:

1. A vapor deposition crucible, comprising a crucible end and a sidewall connected to the crucible end, the sidewall and the crucible end enclosing a hollow chamber, the hollow chamber comprises several inter-connected blind holes and the extending directions consist with the extending direction of the sidewall, an inner surface of the sidewall comprises several first arc shape surfaces curved inward the inner surface of the sidewall, the several first arc shape surfaces are respectively part of the several blind holes.

2. The vapor deposition crucible according to claim 1, wherein the hollow chamber consists of three blind holes at least, that means when the inner surface of the sidewall is comprising at least three first arc shape surfaces, the vapor deposition crucible also comprises a thermal conduction bar located inside the hollow chamber in a case of its bottom is connected with the crucible end; wherein a side surface of the thermal conduction bar is enclosed by several second arc shape surfaces curved inward the surface of thermal conduction bar, the several second arc shape surfaces are respectively part of the several blind holes, that means are respectively located at the same blind holes where the first arc shape surfaces are located; a height of the thermal conduction bar do not exceed two-thirds of a height of the sidewall.

3. The vapor deposition crucible according to claim 1, comprising a metal bar with material cut by mechanical processing.

4. A vapor deposition crucible, comprising a crucible end, a sidewall connected to the crucible end, a thermal conduction bar located in a hollow chamber enclosed by the sidewall and the crucible end, and its bottom connected to the crucible end.

5. The vapor deposition crucible according to claim 4, wherein a height of the thermal conduction bar does not exceed two-thirds of a height of the sidewall; the sidewall is barrel shape, the thermal conduction bar is column shape and located at an axis position of the sidewall.

6. The vapor deposition crucible according to claim 4, comprising a metal bar with material cut by mechanical processing.

7. A vapor deposition crucible, comprising a crucible end, a sidewall connected to the crucible end, several discontinuous thermal conduction plates located in a shallow chamber enclosed by the sidewall and the crucible end, and its bottom is connected to the crucible end.

8. The vapor deposition crucible according to claim 7, wherein the side wall is barrel shape, the several thermal conduction plates are several arc shape thermal conduction plates located at a barrel that is on the same axis with the sidewall; a height of the thermal conduction plate do not exceed two-thirds of a height of the sidewall.

9. The vapor deposition crucible according to claim 7, wherein the side wall is barrel shape, the several thermal conduction plates are straight shape, one side of the thermal conduction plate connected inner surface of the sidewall, the other side extends to the axis of the sidewall; a height of the thermal conduction plate do not exceed two-thirds of a height of the sidewall.

10. The vapor deposition crucible according to claim 7, comprising a metal bar with material cut by mechanical processing.
